(19) United States
(12) Patent Application Publication
(10) Pub. No.: US 2001/0045666 A1
(43) Pub. Date: Nov. 29, 2001

(54) Semiconductor device having self-aligned contact and fabricating method therefor

(75) Inventors: Myeong-cheol Kim, Suwon-city (KR); Byeong-yun Nam, Suwon-city (KR); Gyung-jin Min, Sungdong-gu (KR); Tae-hyuk Ahn, Yongin-city (KR)

Correspondence Address: Mills & Onello LLP, Eleven Beacon Street, Boston, MA, 02108, US

(73) Assignee: Samsung Electronics Co., Ltd.

(21) Appl. No.: 09/731,385

(22) Filed: Dec. 6, 2000

(30) Foreign Application Priority Data
Dec. 6, 1999 (KR) 99-55204

(51) Int. Cl. H01L 23/48; H01L 23/52; H01L 29/40

(52) U.S. Cl. 257/774

(57) ABSTRACT

A semiconductor device having a self-aligned contact and a method for fabricating the same are provided. The semiconductor device includes a plurality of conductive patterns formed to be adjacent to one another by sequentially stacking and patterning a first conductive layer and a mask layer on a particular underlying layer. A first insulation layer fills a gap between adjacent conductive layer patterns such that the upper portion of each conductive layer pattern is exposed. A second insulation layer having a spacer shape is formed on the sides of each conductive layer pattern exposed above the first insulation layer. A second conductive layer fills a contact hole which is self-aligned with respect to the second insulation layers between adjacent conductive layer patterns and passes through the first insulation layer.

### BACKGROUND OF THE INVENTION

1. Field of the Invention

The present invention relates to a semiconductor device and a fabricating method therefor, and more particularly, to a semiconductor device having a self-aligned contact and a fabricating method therefor.

2. Description of the Related Art

As the integration density of semiconductor devices increases, the size of a memory cell rapidly decreases. In the case of a dynamic random access memory (DRAM), a cell size is 1.5 μm² or smaller. A small cell size can be obtained by reducing the gap between conductive layers forming a cell. In particular, in DRAMs having a high integration density, the gap between gate electrodes becomes close to a minimum feature size according to a design rule, and a contact hole for forming a contact between a bit line and a drain region (hereinafter, referred to as a “bit line contact” or a “directed contact”) or a contact between a storage electrode and a source region (hereinafter, referred to as a “storage node contact” or a “buried contact”) becomes close to the minimum feature size.

As the integration density of semiconductor devices increases, the gap between a contact hole connecting a lower interconnection layer to an upper interconnection layer and an adjacent interconnection line decreases, and the aspect ratio of the contact hole increases. Accordingly, there is a limitation in repeatedly realizing a desired process when forming a contact hole using a photolithography process in a highly integrated semiconductor device employing a multiple interconnection layer structure. To overcome the limitation of the photolithography process, a self-aligned contact (SAC) technique of forming a contact hole in a self-aligned mariner was developed.

According to the SAC technique, a line/space type conductive layer pattern is wrapped with a silicon nitride layer. Spaces between the conductive layer patterns are filled with a silicon oxide layer. The silicon oxide layer is partially etched under the etching conditions where the silicon oxide layer is etched faster than the silicon nitride layer so as to form a contact hole, and a conductive material is deposited in the contact hole. Since the silicon nitride layer is a non-conductive material, a short-circuit does not occur between the line/space type conductive layer pattern wrapped with the silicon nitride layer and the conductive material deposited in the contact hole.

However, since the dielectric constant of a silicon nitride layer is about 7.5, parasitic capacitance in the case of an SAC process where a silicon nitride layer insulates a conductive layer pattern from a conductive material in a contact hole is about two times as large as in the case of a normal contact process where a silicon oxide layer having a dielectric constant of about 3.9 insulates a line/space type conductive layer pattern and a conductive material in a contact hole. When such an SAC process is applied to form a storage node contact in a DRAM, bit line capacitance C_{B/L} is larger than that obtained when a normal contact process is applied. The effect of this is the same as if cell capacitance decreases, thereby decreasing data reading sensitivity. In addition, during a self-aligned silicidation (salicidation) process for forming a logic device or a central processing unit of a computer, a silicon nitride layer spacer is applied to a gate. In this case, the parasitic capacitance between a gate and an adjacent conductive contact also increases, causing a decrease in a command transmission rate.

To solve the parasitic capacitance problem, various methods of providing both a silicon nitride layer and a silicon oxide layer on a side of a conductive layer pattern have been proposed. A method of forming a dual spacer composed of a silicon nitride layer and a silicon oxide layer is disclosed in U.S. Pat. No. 5,899,722, and a method of thermal-oxidizing the side of a conductive layer pattern is disclosed in U.S. Pat. No. 5,731,236. However, the former method still results in a larger parasitic capacitance than the case where an entire spacer is formed of only a silicon oxide layer. The latter method is not very effective in reducing parasitic capacitance because the thickness of a silicon oxide layer formed by thermal oxidation is just 100 Å or thinner.

In addition, in the case of an SAC process, a silicon nitride spacer is formed on each side of a conductive layer pattern in a state where the gap between conductive layer patterns is narrow due to the reduction of a design rule in a highly integrated semiconductor device. Accordingly, the gap between conductive layer patterns becomes narrower, so it is more difficult to fill spaces among conductive layer patterns with a silicon oxide layer without forming voids. In particular, it is nearly impossible to fill spaces among conductive layer patterns in one step according to the performance of a conventional deposition process when fabricating a semiconductor device having an extremely high integration density in which a design rule is 0.15 μ.

### SUMMARY OF THE INVENTION

To solve the above problems, it is a first object of the present invention to provide a semiconductor device having a self-aligned contact and a fabricating method therefor, in which the parasitic capacitance between a conductive layer pattern and a conductive contact positioned between conductive layer patterns is minimized, thereby fundamentally eliminating the causes of a drop in data reading sensitivity and a lowering in the operating speed of a device.

It is a second object of the present invention to provide a semiconductor device having a self-aligned contact and a fabricating method therefor, in which spaces among conductive layer patterns are easily filled, and the parasitic capacitance between a conductive layer pattern and a conductive contact positioned between conductive layer patterns can be minimized.

In accordance with the invention, there is provided a semiconductor device having a self-aligned contact. The semiconductor device includes a plurality of conductive patterns formed to be adjacent to one another by sequentially stacking and patterning a first conductive layer and a mask layer on a particular underlying layer. A first insulation layer fills a gap between adjacent conductive layer patterns such that the upper portion of each conductive layer pattern is exposed. A second insulation layer having a spacer shape is formed on the sides of each conductive layer pattern exposed above the first insulation layer. A second conductive layer fills a contact hole which is self-aligned with respect to the second insulation layers between adjacent conductive layer patterns and passes through the first insulation layer.

Taking into account the thickness and the etching rates of the mask layer and the second insulation layer having a spacer shape, the first insulation layer is preferably formed so that its top is either lower or higher than the top of the first conductive layer. The etching rate of the first insulation layer is preferably larger than that of the second insulation layer. Also, the dielectric constant of the first insulation layer is preferably smaller than that of the second insulation layer.

A third insulation layer may be further provided between the first insulation layer and the sides of each conductive layer pattern and between the second insulation layer and the side of the conductive layer pattern. Also, a fourth insulation layer may be further provided on the surface of the underlying layer except for a portion contacting the second conductive layer and on the surfaces of the conductive layer patterns.

The underlying layer may be a semiconductor substrate or a particular material layer formed on the semiconductor substrate. The second conductive layer may directly contact the semiconductor substrate or may contact a conductive pad layer formed on the semiconductor substrate. The second conductive layer may be formed to at least partially contact a field oxide layer formed on the surface of the semiconductor substrate.

The first conductive layer of each conductive layer pattern may be a bit line or a gate electrode.

In accordance with another aspect of the invention, there is provided a method for fabricating a semiconductor device having a self-aligned contact. According to the method, a plurality of conductive layer patterns are formed adjacent to one another by sequentially stacking a first conductive layer and a mask layer on a particular underlying layer and patterning them. A gap between adjacent conductive layer patterns is filled by depositing a first insulation layer on the surface of the underlying layer on which the conductive layer patterns are formed. The entire surface of the first insulation layer is etched to expose the upper portion of each conductive layer pattern. A spacer of a second insulation layer is formed on the sides of each exposed conductive layer pattern. A contact hole is formed self-aligned with respect to spacers so that the surface of the underlying layer between adjacent conductive layer patterns is exposed. A second conductive layer is formed by filling the contact hole with a conductive material.

The method may further include planarizing the surface of the first insulation layer after filling the gap between the adjacent conductive layer patterns with the first insulation layer, in order to ensure the uniformity of the thickness of the first insulation layer. The method may also include forming an interlayer insulation layer, the surface of which is planarized, on the entire surface of the resultant structure obtained after forming the spacer of the second insulation layer, in order to improve the surface morphology during a later process.

The method may also include forming an insulation layer used as an etching stopper on the entire surface of the resultant structure obtained after forming the conductive layer patterns. The method may also include forming a spacer of the insulation layer used as the etching stopper on each side of each conductive layer pattern by etching the insulation layer used as the etching stopper.

According to the present invention, the first insulation layer having a relatively smaller dielectric constant is provided between the first conductive layer of each conductive layer pattern and the second conductive layer between adjacent conductive layer patterns, thereby considerably decreasing parasitic capacitance occurring between the first and second conductive layers. Therefore, the reading performance and the operating speed of a semiconductor device can be greatly increased. In addition, since the gap between adjacent conductive layer patterns is previously filled with the first insulation layer before forming the spacer on each side of each conductive layer pattern and then a contact hole self-aligned with the spacer of the second insulation layer is formed, the gap between the adjacent conductive layer patterns can be easily filled without forming voids.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a schematic sectional view illustrating a semiconductor device having a self-aligned contact according to a first embodiment of the present invention.

FIG. 2 is a schematic sectional view illustrating a semiconductor device having a self-aligned contact according to a second embodiment of the present invention.

FIG. 3 is a schematic sectional view illustrating a semiconductor device having a self-aligned contact according to a third embodiment of the present invention.

FIG. 4 is a schematic sectional view illustrating a semiconductor device having a self-aligned contact according to a fourth embodiment of the present invention.

FIG. 5 is a schematic sectional view illustrating a semiconductor device having a self-aligned contact according to a fifth embodiment of the present invention.

FIGS. 6A through 6F are schematic sectional views illustrating a method for fabricating a semiconductor device having a self-aligned contact according to the first embodiment of the present invention.

FIGS. 7A through 7C are schematic sectional views illustrating a method for fabricating a semiconductor device having a self-aligned contact according to the second embodiment of the present invention.

FIGS. 8A through 8C are schematic sectional views illustrating a method for fabricating a semiconductor device having a self-aligned contact according to the third embodiment of the present invention.

FIGS. 9A and 9B are schematic sectional views illustrating a method for fabricating a semiconductor device having a self-aligned contact according to the fourth embodiment of the present invention.

FIGS. 10A and 10B are schematic sectional views illustrating a method for fabricating a semiconductor device having a self-aligned contact according to the fifth embodiment of the present invention.

### DETAILED DESCRIPTION OF PREFERRED EMBODIMENTS

Hereinafter, embodiments of the present invention will be described in detail with reference to the attached drawings. The present invention is not restricted to the following embodiments, and many variations are possible within the spirit and scope of the present invention. The embodiments of the present invention are provided in order to more completely describe the present invention to those skilled in the art. In the drawings, the thicknesses of members or regions are exaggerated for clarity. Also, when it is stated that a layer is formed “on” another layer or a substrate, the layer can be formed directly on the other layer or the substrate, or other layers can intervene therebetween.

In describing the embodiments of the present invention, as an example of an underlying layer, a semiconductor substrate is described, but the underlying layer of the present invention may be a particular material layer formed on the semiconductor substrate. A self-aligned contact formed between conductive layer patterns may directly contact the surface of the semiconductor substrate, or may be formed in a portion so that it can contact a conductive pad layer formed on the semiconductor substrate or the surface of another underlying conductive layer.

### First Embodiment

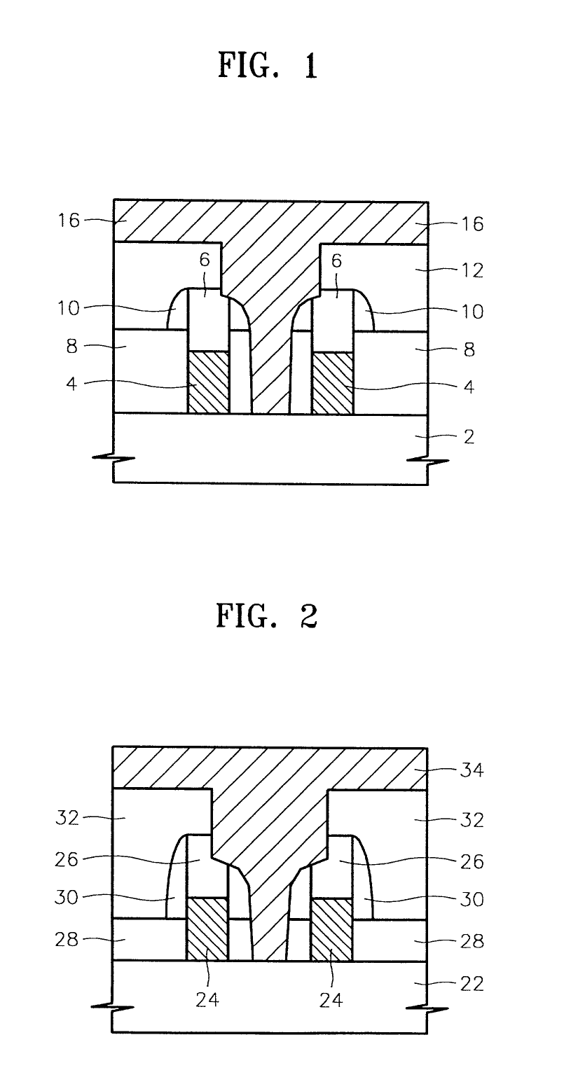

FIG. 1 is a sectional view illustrating a semiconductor device having a self-aligned contact according to a first embodiment of the present invention. Referring to FIG. 1, a first conductive layer 4 and a mask layer 6 are sequentially stacked on a semiconductor substrate 2 and patterned, thereby forming conductive layer patterns in the form of a line and a space. The space between the conductive patterns is filled such that a first insulation layer 8 is formed to partially expose the sides of the conductive patterns, and second insulation layers 10 are formed in a spacer shape surrounding the exposed sides of the conductive layer patterns.

The resultant structure is covered with an interlayer insulation layer 12 having a planarized surface. A contact hole passing through the interlayer insulation layer 12 and the first insulation layer 8 and exposing the semiconductor substrate 2 between the conductive layer patterns is formed. The contact hole is filled with a conductive material layer, thereby forming a second conductive layer 16. To simplify the drawing, the second conductive layer 16 is illustrated as including a contact filling only the contact hole and an interconnection layer (for example, a storage electrode layer of a semiconductor capacitor) formed on the interlayer insulation layer 12. The contact and the interconnection layer may be formed of different conductive material layers and separate members or may be the same member formed of the same conductive material layer.

In this embodiment, the first insulation layer 8 and the interlayer insulation layer 12 are formed of silicon oxide (SiO₂), and the mask layer 6 and the second insulation layer 10 are formed of silicon nitride. The top surface of the first insulation layer 8 is higher than the top surface of the first conductive layer 4.

Although the first conductive layer 4 and the first insulation layer 8 are illustrated as being directly formed on the semiconductor substrate 2, they may be formed on a particular conductive or insulating material layer formed on the semiconductor substrate 2. The second conductive layer 16 may contact the surface of an active area in the semiconductor substrate 2, the surface of a field oxide layer (not shown) formed on the surface of the semiconductor substrate 2, or the surface of the junction area between the active region and the field oxide layer. The second conductive layer 16 may contact the surface of a conductive pad layer (not shown) formed on the semiconductor substrate 2.

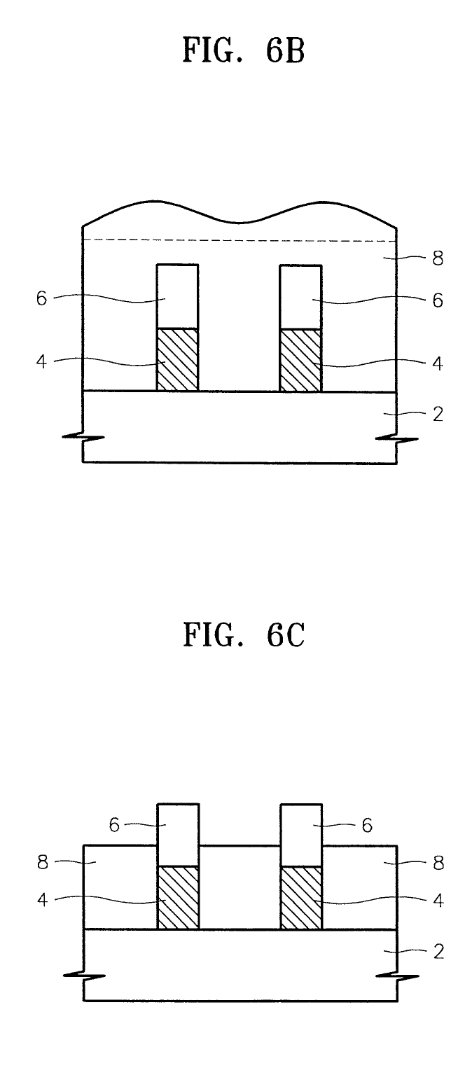

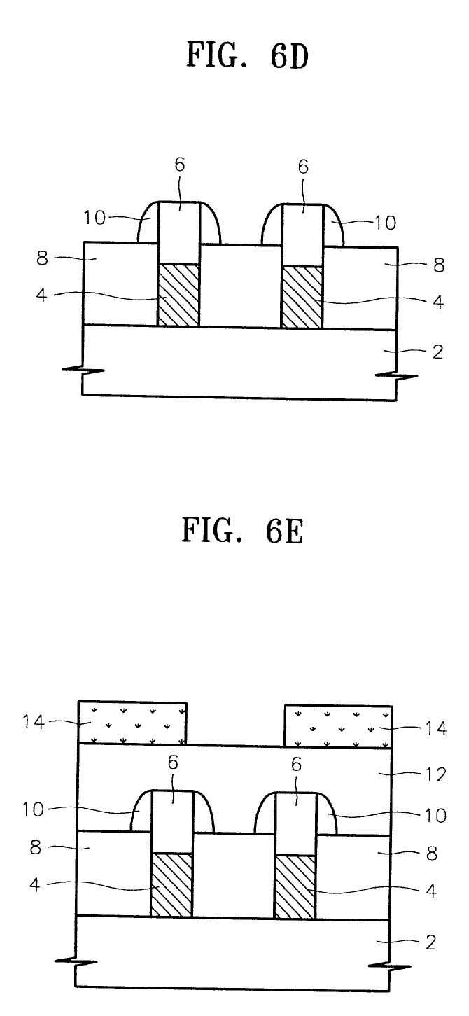

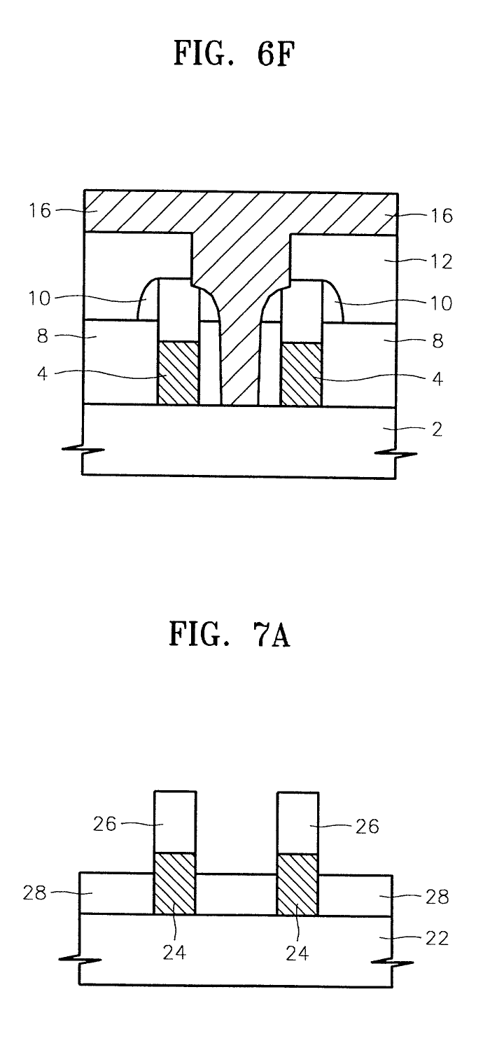

FIGS. 6A through 6F are sectional views illustrating a method for fabricating a semiconductor device having a self-aligned contact according to the first embodiment of the present invention shown in FIG. 1. Referring to FIG. 6A, a conductive material is deposited on the semiconductor substrate 2, thereby forming a first conductive layer 4. Next, to deposit a material for protecting an underlying conductive layer while an oxide layer is being etched to form a self-aligned contact in a succeeding process, for example, a silicon nitride (SiN) layer is deposited on the first conductive layer 4 by a plasma enhanced chemical vapor deposition (PECVD), thereby forming a mask layer 6. Subsequently, the mask layer 6 and the first conductive layer 4 are sequentially anisotropically etched by a photolithographic process, thereby forming conductive layer patterns. Consequently, the conductive layer patterns are formed by sequentially stacking and patterning the first conductive layer 4 and the mask layer 6.

Referring to FIG. 6B, a silicon oxide (SiO₂) layer is deposited on the entire surface of the resultant structure by a chemical vapor deposition (CVD) method so that the gap between the conductive layer patterns can be completely filled with the silicon oxide layer, thereby forming a first insulation layer 8. Here, since the silicon oxide layer is deposited in a state where spacers are not formed on the sides of each of the conductive layer patterns, the gap can be easily filled with the silicon oxide layer without formation of voids.

Next, the first insulation layer 8 may be polished down to a predetermined thickness by a chemical mechanical polishing (CMP) process in order to make the thickness of the first insulation layer 8 uniform (the result is represented by a dotted line in the drawing). However, when the thickness of the first insulation layer 8 formed by deposition is uniform, the CMP process can be omitted.

Referring to FIG. 6C, the entire surface of the first insulation layer 8 is wet-etched using an oxide layer etchant such as a hydrofluoride (HF) solution. When the amount of the second insulation layer 10 etched in a vertical direction is smaller than the thickness of the mask layer 6, taking into account the thicknesses of the mask layer 6 and the second insulation layer 10 and the etching rates of these layers during a later self-aligned contact (SAC) process described with reference to FIG. 1, the first insulation layer 8 is etched such that the top of the first insulation layer 8 is higher than the top of the conductive layer 4, that is, the first insulation layer 8 is etched down to the middle of the mask layer 6, as shown in FIG. 6C.

Referring to FIG. 6D, A silicon nitride layer for a spacer is deposited on the resultant structure by, for example, a low pressure CVD (LPCVD) method, to a predetermined thickness. Next, the silicon nitride layer is anisotropically etched, thereby forming second insulation layers 10 having a spacer shape on the sides of each mask layer 6 exposed over the first insulation layer 8. Here, the silicon nitride layer is anisotropically etched until the surface of the first insulation layer 8 is exposed. The mask layer 6 formed of silicon nitride may also etched, but this can be ignored.

Referring to FIG. 6E, a silicon oxide layer is deposited on the entire surface of the resultant structure including the second insulation layer 10 having a spacer shape, thereby forming an interlayer insulation layer 12. The surface of the interlayer insulation layer 12 is planarized by a CMP process to facilitate a later process of forming a contact hole. Subsequently, a photolithographic process is performed on the planarized interlayer insulation layer 12, thereby forming a photoresist pattern 14 exposing an area where a contact hole is to be formed. Alternatively, after formation of the second insulation layer 10 having a spacer shape, a photoresist layer may be directly deposited on the entire surface of the resultant structure without forming the interlayer insulation layer 12, and then a photolithographic process may performed to form the photoresist pattern 14 exposing an area where a contact hole is to be formed.

Referring to FIG. 6F, the interlayer insulation layer 12 and the first insulation layer 8 are sequentially anisotropically etched using the photoresist pattern 14 and the second insulation layer 10 as a mask, thereby forming a contact hole exposing the semiconductor substrate 2 between the conductive layer patterns. The first insulation layer 8 between the conductive layer patterns 4, 6 is anisotropically etched in a self-aligned manner using the mask layer 6 and the second insulation layers 10 having a spacer shape formed on the sides of the mask layer 6. Next, a conductive material is deposited on the resultant structure, thereby forming a second conductive layer 16 contacting the semiconductor substrate 2. Alternatively, the second conductive layer 16 may be formed by forming a contact by filling the contact hole with a conductive material layer and then forming an interconnection layer by depositing a conductive material layer on the interlayer insulating layer 12 and performing a photolithographic process.

According to the first embodiment of the present invention, only the first insulation layer 8 formed of a silicon oxide layer having a relatively low dielectric constant exists between the first conductive layer 4 and the second conductive layer 16 so that parasitic capacitance can be decreased compared to a conventional structure having a silicon nitride layer as a single spacer.

In addition, the gap between the conductive layer patterns is filled with a silicon oxide layer in a state where spacers are not formed on the sides of each of the conductive layer patterns so that the gap can be easily filled without formation of voids.

### Second Embodiment

FIG. 2 is a sectional view of a semiconductor device having a self-aligned contact according to a second embodiment of the present invention. The semiconductor device of FIG. 2 is fundamentally the same as that according to the first embodiment, with the exception that the top of a first insulation layer 28 is lower than the top of the first conductive layer 24. In FIG. 2, reference numeral 22 denotes a semiconductor substrate, reference numeral 26 denotes a mask layer, reference numeral 30 denotes a second insulation layer, reference numeral 32 denotes an interlayer insulation layer, and reference numeral 34 denotes a second conductive layer. A detailed description of members which are the same as those in the first embodiment will be omitted.

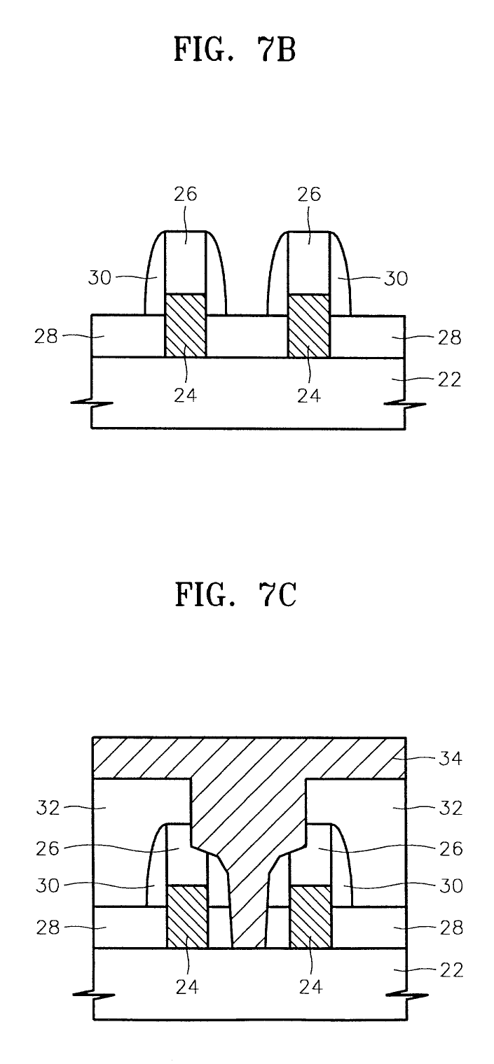

FIGS. 7A through 7C are sectional views illustrating a method for fabricating a semiconductor device having a self-aligned contact according to the second embodiment of the present invention shown in FIG. 2. This method can be effective when the second insulation layer 30 formed of a silicon nitride layer having a spacer shape has a large vertical etching rate during formation of a self-aligned contact hole.

Referring to FIG. 7A, conductive layer patterns are formed by sequentially stacking and patterning a first conductive layer 24 and a mask layer 26 on a semiconductor substrate 22 in the same manner as in the first embodiment, and a first insulation layer 28 is deposited on the entire surface of the resultant structure. Next, the entire surface of the first insulation layer 28 is wet-etched so that the top of the first insulation layer 28 is lower than the top of the first conductive layer 24, unlike the first embodiment, and an upper side portion of the first conductive layer 24 is exposed.

Referring to FIG. 7B, an LPCVD nitride layer is deposited on the resultant structure, and an anisotropic etching process is performed, thereby forming second insulation layers 30 having a spacer shape on the sides of the mask layer 26 and the exposed upper side portion of the first conductive layer 24. Unlike the first embodiment, the height of the second insulation layer 30 is larger than the height of the mask layer 26.

Referring to FIG. 7C, an interlayer insulation layer 32 is deposited on the entire surface of the resultant structure including the second insulation layer 30 having a spacer shape, and then the surface of the interlayer insulation layer 32 is planarized. A photolithographic process is performed on the planarized interlayer insulation layer 32, thereby allowing a photoresist pattern (not shown) to define an area where a contact hole is to be formed. Here, as described in the first embodiment, an interlayer insulation layer 32 may not be formed. The interlayer insulation layer 32 and the first insulation layer 28 in the area defined by the photoresist pattern are sequentially anisotropically etched, thereby exposing the semiconductor substrate 22 and forming a contact hole self-aligned by the second insulation layer 30 having a spacer shape. Next, a second conductive layer 34 filling the contact hole is formed contacting the semiconductor substrate 22.

In the second embodiment of the present invention, although the first insulation layer 28 formed of a silicon oxide layer having a small dielectric constant and the spacer-shaped second insulation layer 30 formed of a silicon nitride layer having a relatively larger dielectric constant coexist between the first conductive layer 24 and the second conductive layer 34, parasitic capacitance between the first conductive layer 24 and the second conductive layer 34 can be considerably reduced compared to a conventional semiconductor device having only a silicon nitride layer between two conductive layers, and a self-aligned contact structure can be realized without forming voids.

### Third Embodiment

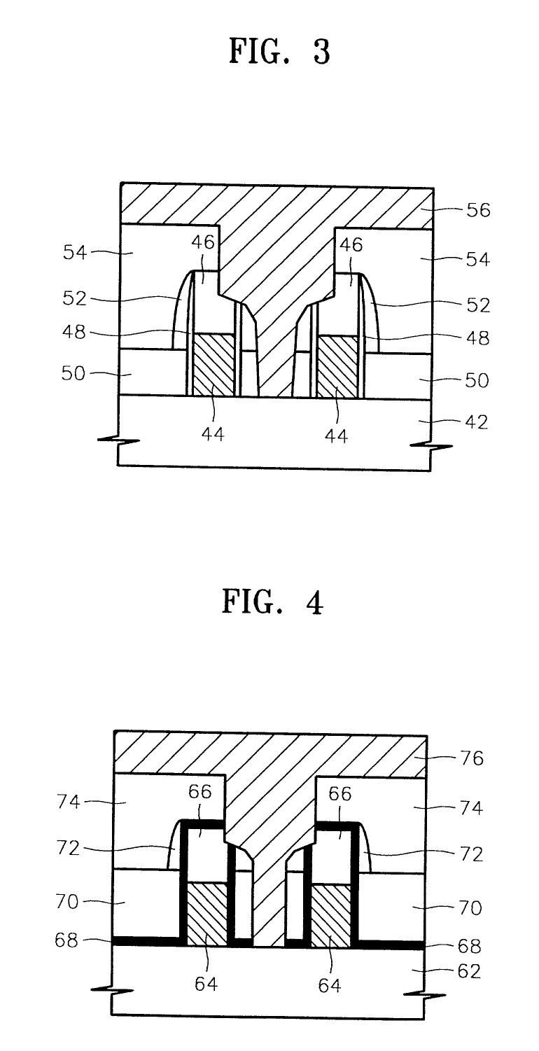

FIG. 3 is a sectional view of a semiconductor device having a self-aligned contact according to a third embodiment of the present invention. Compared to the first embodiment, in the semiconductor device of FIG. 3, the top of a first insulation layer 50 is lower than the top of the first conductive layer 44, and third insulation layers 48 made of, for example, a silicon nitride layer, are further formed as etching stoppers on the sides of a conductive layer pattern. The third insulation layer 48 serves to protect the first conductive layer 44 during a later SAC process performed with respect to the first insulation layer 50. In FIG. 3, reference numeral 42 denotes a semiconductor substrate, reference numeral 46 denotes a mask layer, reference numeral 52 denotes a second insulation layer, reference numeral 54 denotes an interlayer insulation layer, and reference numeral 56 denotes a second conductive layer.

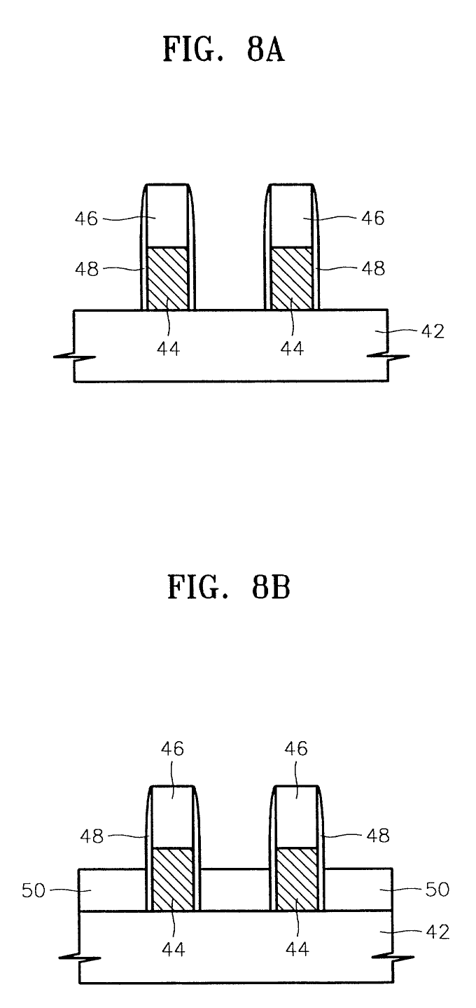

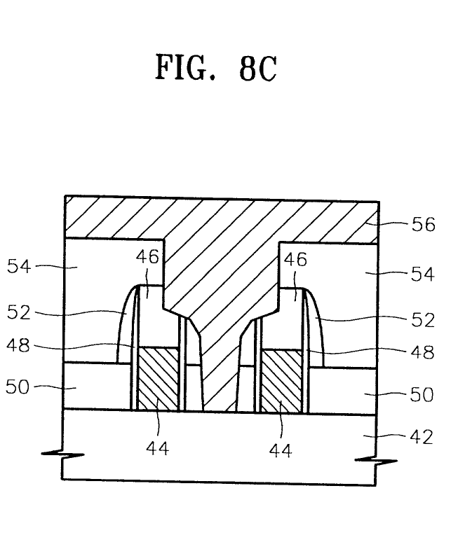

FIGS. 8A through 8C are sectional views illustrating a method for fabricating a semiconductor device having a self-aligned contact according to the third embodiment of the present invention shown in FIG. 3. This method can be effective when the spacer-shaped second insulation layer 52 has a large vertical etching rate during an SAC process, and when the first conductive layer 44 is formed of a material that is corroded by an etchant for etching the interlayer insulation layer 54 or the first insulation layer 50.

Referring to FIG. 8A, a conductive layer pattern composed of a first conductive layer 44 and a mask layer 46 is formed on a semiconductor substrate 42. A silicon nitride layer is deposited on the surface of the resultant structure to a thickness of 50-200 Å, preferably, 150 Å, and then anisotropically etched, thereby forming spacer-shaped third insulation layers 48 on the sides of the conductive layer pattern. The third insulation layer 48 is formed to prevent the first conductive layer 44 from being corroded where an interlayer insulation layer 54 and a first insulation layer 50 which are formed of silicon oxide are wet-etched later.

Referring to FIG. 8B, the first insulation layer 50 is deposited on the surface of the resultant structure having the third insulation layer 48, thereby filling the gap between conductive layer patterns. The entire surface of the first insulation layer 50 is wet-etched so that the top of the first insulation layer 50 is lower than the top of the first conductive layer 44.

Even if the first conductive layer 44 is formed of a material such as tungsten silicide (WSi) that can be corroded by a silicon oxide layer etchant, it is not corroded where the first insulation layer 50 is wet-etched because the third insulation layers 48 for stopping etching are formed on the sides of the first conductive layer.

Referring to the FIG. 8C, an LPCVD nitride layer is deposited on the resultant structure, and an anisotropic etching process is performed, thereby forming second insulation layers 52 having a spacer shape on the sides of the mask layer 46 and the exposed upper side portion of the first conductive layer 44. An interlayer insulation layer 54 is deposited on the entire surface of the resultant structure including the second insulation layer 52 having a spacer shape, and then the surface of the interlayer insulation layer 54 is planarized. A photolithographic process is performed on the planarized interlayer insulation layer 54 to define an area where a contact hole is to be formed. Next, the interlayer insulation layer 54 and the first insulation layer 50 in the defined area are sequentially anisotropically etched, thereby exposing the semiconductor substrate 42 and forming a contact hole self-aligned by the second insulation layer 52 having a spacer shape. Subsequently, the contact hole is filled with a conductive material, thereby forming a second conductive layer 56.

The third embodiment of the present invention facilitates filling of the gap between the conductive layer patterns and considerably decreases parasitic capacitance between the first conductive layer 44 and the second conductive layer 56. In addition, even if the first conductive layer 44 is formed of a material that can be corroded by an etchant used during an SAC process, it is not corroded because it is protected by the third insulation layer 48 formed on the sides of the first conductive layer 44.

### Fourth Embodiment

FIG. 4 is a sectional view illustrating a semiconductor device having a self-aligned contact according to a fourth embodiment of the present invention. The structure of FIG. 4 is shown when the present invention is applied to a pad SAC structure. When the present invention is applied to the pad SAC structure, since a contact hole formed between conductive layer patterns such as gate electrodes exposes both an active region and a field oxide layer in a semiconductor substrate, the field oxide layer may be corroded during an etching process for forming the self-aligned contact hole. The fourth embodiment is provided for preventing the field oxide layer from being corroded during the etching process. In FIG. 4, reference numeral 62 denotes a semiconductor substrate, reference numeral 64 denotes a first conductive layer, i.e., a gate electrode, reference numeral 66 denotes a mask layer, reference numeral 68 denotes a fourth insulation layer formed of a silicon nitride layer used as an etching stopper, reference numeral 70 denotes a first insulation layer formed of a silicon oxide layer, reference numeral 72 denotes a second insulation layer formed of a silicon nitride layer, reference numeral 74 denotes an interlayer insulation layer formed of silicon oxide layer, and reference numeral 76 denotes a second conductive layer.

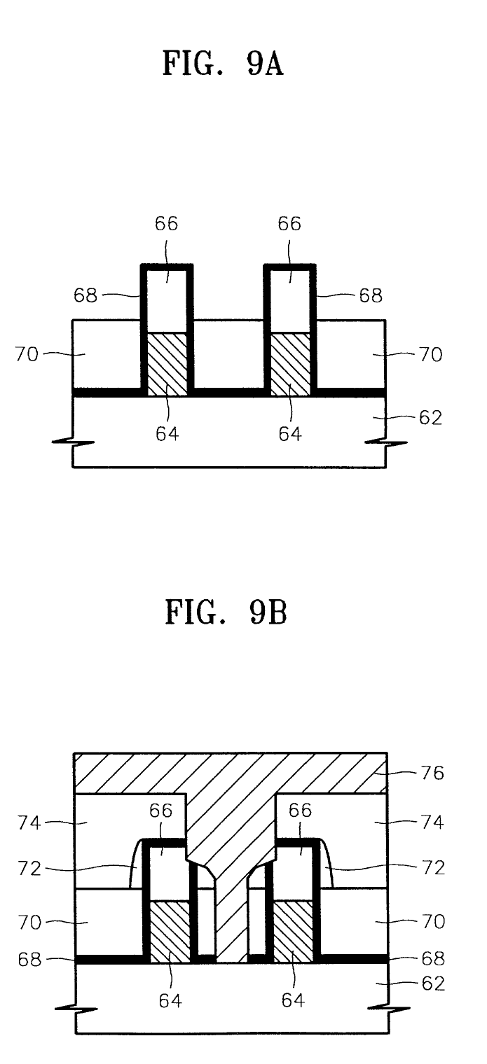

FIGS. 9A and 9B are sectional views illustrating a method for fabricating a semiconductor device having a self-aligned contact according to the fourth embodiment of the present invention shown in FIG. 4. This method is applied to semiconductor device fabrication using a pad SAC process.

Referring to FIG. 9A, a conductive layer pattern composed of a first conductive layer 64 and a mask layer 66 is formed on a semiconductor substrate 62. A material such as a silicon nitride layer having a large etching selection ratio with respect to a silicon oxide layer is deposited on the entire surface of the resultant structure to a thickness of 50-200 Å, thereby forming a fourth insulation layer 68 for preventing corrosion of a field oxide layer (not shown) formed on a certain portion of the surface of the semiconductor substrate 62. Next, a silicon oxide layer is deposited on the entire surface of the resultant structure and then wet-etched, thereby forming a first insulation layer 70 so that the top of the first insulation layer 70 is higher than the top of the first conductive layer 64. The fourth insulation layer 68 serves to protect the sides of the first conductive layer 64 while the first insulation layer 70 is being wet-etched.

Referring to FIG. 9B, a spacer-shaped second insulation layer 72 made of a silicon nitride layer is formed on the sides of the mask layer 66, and then an interlayer insulation layer 74 is formed on the entire surface of the resultant structure. Thereafter, a photolithographic process is performed to anisotropically etch the interlayer insulation layer 74 and the first insulation layer 70 in a self-aligned manner with respect to the second insulation layer 72. Next, the fourth insulation layer 68 used as an etching stopper remaining on the bottom of an area where an SAC will be formed is removed by dry-etching, thereby forming a contact hole exposing the semiconductor substrate 62. Subsequently, the contact hole is filled with a conductive material, thereby forming a second conductive layer 76.

### Fifth Embodiment

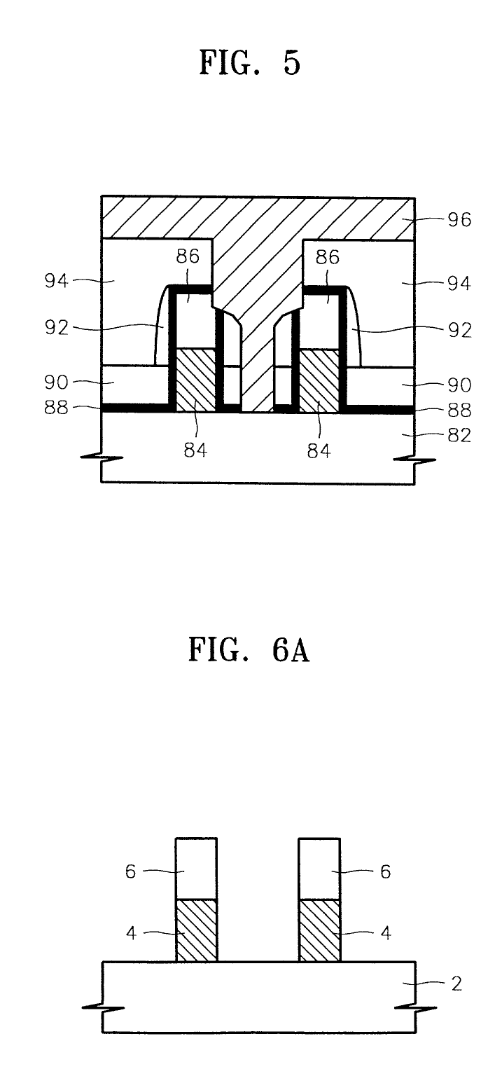

FIG. 5 is a sectional view illustrating a semiconductor device having a self-aligned contact according to a fifth embodiment of the present invention. Like the fourth embodiment, the structure of FIG. 5 is shown when the present invention is applied to a pad SAC structure. In FIG. 5, reference numeral 82 denotes a semiconductor substrate, reference numeral 84 denotes a first conductive layer, i.e., a gate electrode, reference numeral 86 denotes a mask layer, reference numeral 88 denotes a fourth insulation layer, reference numeral 90 denotes a first insulation layer formed of a silicon oxide layer, reference numeral 92 denotes a second insulation layer formed of a silicon nitride layer, reference numeral 94 denotes an interlayer insulation layer formed of silicon oxide layer, and reference numeral 96 denotes a second conductive layer.

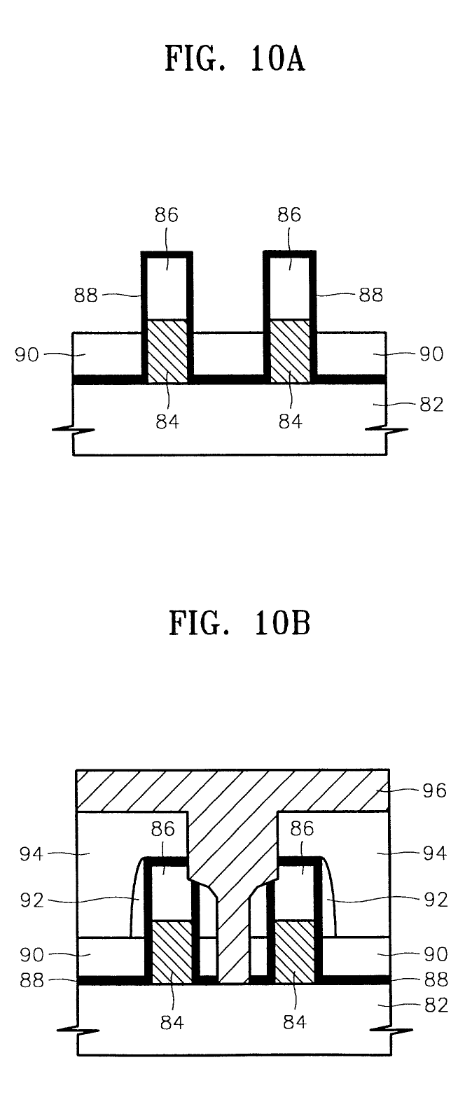

FIGS. 10A and 10B are sectional views illustrating a method for fabricating a semiconductor device having a self-aligned contact according to the fifth embodiment of the present invention shown in FIG. 5. Like the fourth embodiment, this method is applied to semiconductor device fabrication using a pad SAC process.

Referring to FIG. 10A, a conductive layer pattern composed of a first conductive layer 84 and a mask layer 86 is formed on a semiconductor substrate 82, and then a fourth insulation layer 88 used as an etching stopper is deposited on the entire surface of the resultant structure to a thickness of 50-200 Å. Like the fourth embodiment, the fourth insulation layer 88 prevents the first conductive layer 84 from being corroded during a later process of wet-etching the first insulation layer 90 and protects a field oxide layer (not shown) during a process of anisotropically etching the first insulation layer 90 to form a contact hole. Next, the entire surface of the first insulation layer 90 is wet-etched so that the top of the first insulation layer 90 is lower than the top of the first conductive layer 84.

Referring to FIG. 10B, formation of a second insulation layer 92 having a spacer shape, deposition and planarization of the interlayer insulation layer 94, and a photolithographic process are sequentially performed, thereby forming a self-aligned contact hole exposing the semiconductor substrate 82. The contact hole is filled with a conductive material, thereby forming a second conductive layer 96.

According to the above-described embodiments of the present invention, a material having a relatively smaller dielectric constant is provided between a first conductive layer used as a gate electrode or a bit line and a second conductive layer filling a self-aligned contact hole positioned between first conductive layers, thereby considerably decreasing parasitic capacitance. Therefore, the reading performance and the operating speed of a device can be greatly increased. In addition, since a filling process is performed before forming spacers on the sides of a conductive layer pattern, the filling process can be easily performed without forming voids. When an etching stopper is formed on a side of a conductive layer pattern in advance, or when an etching stopper covering the entire surface of an exposed conductive layer pattern is further formed, corrosion of a first conductive layer or a field oxide layer can be prevented during a later SAC etching process.

While this invention has been particularly shown and described with references to preferred embodiments thereof, it will be understood by those skilled in the art that various changes in form and details may be made therein without departing from the spirit and scope of the invention as defined by the following claims.

What is claimed is:

1. A semiconductor device having a self-aligned contact, the semiconductor device comprising:
a plurality of conductive patterns formed to be adjacent to one another by sequentially stacking and patterning a first conductive layer and a mask layer on a particular underlying layer;
a first insulation layer filling a gap between adjacent conductive layer patterns such that the upper portion of each conductive layer pattern is exposed;
a second insulation layer having a spacer shape, the second insulation layer formed on the sides of each conductive layer pattern exposed above the first insulation layer; and
a second conductive layer filling a contact hole which is self-aligned with respect to the second insulation layers between adjacent conductive layer patterns and which passes through the first insulation layer.

2. The semiconductor device of claim 1, wherein the top of the first insulation layer is lower than the top of the first conductive layer of each conductive layer pattern.

3. The semiconductor device of claim 1, wherein the top of the first insulation layer is higher than the top of the first conductive layer of each conductive layer pattern.

4. The semiconductor device of claim 1, wherein an etching rate of the first insulation layer is larger than that of the second insulation layer.

5. The semiconductor device of claim 1, wherein the dielectric constant of the first insulation layer is smaller than that of the second insulation layer.

6. The semiconductor device of claim 1, wherein the first insulation layer is formed of a silicon oxide layer.

7. The semiconductor device of claim 1, wherein the second insulation layer is formed of a silicon nitride layer.

8. The semiconductor device of claim 1, further comprising a third insulation layer provided between the first insulation layer and the sides of each conductive layer pattern and between the second insulation layer and the side of the conductive layer pattern.

9. The semiconductor device of claim 8, wherein the third insulation layer is formed of a silicon nitride layer to a thickness of 50-200 Å.

10. The semiconductor device of claim 1, further comprising a fourth insulation layer provided on the surface of the underlying layer except for a portion contacting the second conductive layer and on the surfaces of the conductive layer patterns.

11. The semiconductor device of claim 10, wherein the fourth insulation layer is formed of a silicon nitride layer to a thickness of 50-200 Å.

12. The semiconductor device of claim 11, further comprising a field oxide layer formed on a certain portion of the surface of the underlying layer, wherein the second conductive layer is formed to at least partially contact the field oxide layer.

13. The semiconductor device of claim 11, further comprising a conductive pad layer formed on a certain portion of the surface of the underlying layer, wherein the second conductive layer is formed to contact the surface of the conductive pad layer.

14. The semiconductor device of claim 1, wherein the first conductive layer of each conductive layer pattern is a bit line, and the second conductive layer serves to connect a storage electrode of a semiconductor capacitor to a semiconductor substrate.

15. The semiconductor device of claim 1, wherein the first conductive layer of each conductive layer pattern is a gate electrode, and the contact contacts the surface of a semiconductor substrate.

16. A method for fabricating a semiconductor device having a self-aligned contact, the method comprising:
forming a plurality of conductive layer patterns adjacent to one another by sequentially stacking a first conductive layer and a mask layer on a particular underlying layer and patterning the first conductive layer and the mask layer;
filling a gap between adjacent conductive layer patterns by depositing a first insulation layer on the surface of the underlying layer on which the conductive layer patterns are formed;
etching the entire surface of the first insulation layer to expose the upper portion of each conductive layer pattern;
forming a spacer of a second insulation layer on the sides of each exposed conductive layer pattern;
forming a contact hole self-aligned with respect to spacers so that the surface of the underlying layer between adjacent conductive layer patterns is exposed; and
forming a second conductive layer by filling the contact hole with a conductive material.

17. The method of claim 16, further comprising planarizing the surface of the first insulation layer after filling the gap between the adjacent conductive layer patterns with the first insulation layer.

18. The method of claim 16, further comprising forming an interlayer insulation layer, the surface of which is planarized, on the entire surface of the resultant structure obtained after forming the spacer of the second insulation layer.

19. The method of claim 16, further comprising forming an insulation layer used as an etching stopper on the entire surface of the resultant structure obtained after forming the conductive layer patterns.

20. The method of claim 19, further comprising forming a spacer of the insulation layer used as the etching stopper on the sides of each conductive layer pattern by etching the insulation layer used as the etching stopper.
